(19) United States
(12) Patent Application Publication
(10) Pub. No.: US 2008/0135976 A1
(43) Pub. Date: Jun. 12, 2008

(54) SEMICONDUCTOR DEVICE AND METHOD OF MANUFACTURING THE SAME

(75) Inventor: Keita ODAJIMA, Hukaya-shi (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD., Moriguchi-shi (JP); SANYO SEMICONDUCTOR CO., LTD., Ora-gun (JP)

(21) Appl. No.: 11/951,041

(22) Filed: Dec. 5, 2007

(30) Foreign Application Priority Data
Dec. 7, 2006 (JP) 2006-330148

(51) Int. Cl. H01L 29/00; H01L 21/762

(52) U.S. Cl. 257/513; 438/444; 257/E29.001; 257/E21.553

(57) ABSTRACT

A plurality of trenches are provided in a semiconductor layer and integrated by thermal oxidation to form an insulating region having void parts therein. The thickness of the insulating region can be controlled by the depth of the trenches. This makes it possible to form the insulating region having a thickness larger than that formed by using a conventional LOCOS method, without increasing crystal defects and the like. By providing the insulating region, for example, below an electrode pad, a stray capacitance can be reduced. Moreover, the stray capacitance can be further reduced by the void parts inside the insulating region.

This application claims priority from Japanese Patent Application Number JP2006-330148 filed Dec. 7, 2006, the content of which is incorporated herein by reference in its entirety.

### BACKGROUND OF THE INVENTION

1. Field of the Invention

The present invention relates to a semiconductor device and a method of manufacturing the semiconductor device, and more particularly relates to a high-frequency semiconductor device in which reduction in a capacitance of an insulating region is achieved and a method of manufacturing the high-frequency semiconductor device.

2. Description of the Related Art

In a semiconductor device used in a high-frequency band, particularly, an ultra-high frequency semiconductor device operated in a GHz band or higher, reduction in a stray capacitance of electrode wiring is demanded for improving high-frequency characteristics such as PG (Power Gain) characteristics. Particularly, since a bonding pad has a large area immediately below an electrode, it is necessary to reduce the stray capacitance of the bonding pad. Thus, in an ultra-high frequency transistor and the like, a thickness of an oxide film immediately below the bonding pad is increased by use of a LOCOS (local oxidation of silicon) method, a shallow-etching LOCOS method or the like to reduce the stray capacitance. This technology is described for instance in Japanese Patent Application Publication No. 2005-51160.

However, in the case where a thick oxide film is formed by use of the LOCOS method, there are problems such as an increase in defects due to an increase of a bird's beak in size, an increase in defects caused by a long period of high-temperature oxidation, and an increase in the amount of impurities in a high-concentration substrate to be diffused into a low-concentration epitaxial layer. In consideration of the problems as described above, the limit of the thickness of the oxide film that can be currently used in the ultra-high frequency semiconductor device is about 12,000 Å.

Moreover, although a step coverage can be reduced by use of the shallow-etching LOCOS method, the thickness is similarly limited to about 12,000 Å due to an increase in defects caused by an increase of a bird's beak in size or an increase in defects caused by an increase in oxidation time.

Furthermore, there has been also known a method for reducing an area of a first layer electrode portion having a large stray capacitance and for increasing an area of a second layer electrode portion having a relatively small stray capacitance, by employing a multilayer electrode wiring structure. However, when the multilayer electrode wiring structure is used, the number of processes is increased. Moreover, an interlayer insulating film is required between the first layer electrode portion and the second layer electrode portion. It is desirable to use a nitride film as the interlayer insulating film because of its denseness. However, since the nitride film has a high permittivity, a stray capacitance thereof is larger than that in an oxide film having the same thickness. Thus, it is necessary to increase a thickness of the nitride film.

### SUMMARY OF THE INVENTION

The invention provides a semiconductor device including a semiconductor layer having an element region and an insulating region. The device also includes a semiconductor element formed in the element region. The insulating region includes an insulating film formed in the semiconductor layer to define a void.

The invention also provides a method of manufacturing a semiconductor device. The method includes providing a semiconductor layer, forming a trench in the semiconductor layer, forming an insulating film in the trench so as not to fill the trench completely so that a void is formed in the trench, forming a cover film on the trench, and forming an semiconductor element in the semiconductor layer outside the trench.

The invention provides another method of manufacturing a semiconductor device. The method includes providing a semiconductor layer, forming a plurality of trenches in the semiconductor layer; thermally oxidizing inside walls of the trenches so as to grow an insulating film so that voids are formed in the trenches, forming a cover film on the trenches, and forming an semiconductor element in the semiconductor layer outside the trenches. The oxidation of the inside walls of the trenches is performed so that portions of the semiconductor layer between the trenches are completely oxidized.

The invention further provides a semiconductor device including a semiconductor substrate, a semiconductor element formed on the substrate, an electrode pad formed on the substrate and connected to the semiconductor element, and an insulating region formed in the substrate under the electrode pad and having an insulating portion and an void portion defined by the insulating portion.

### BRIEF DESCRIPTION OF THE DRAWINGS

FIG. 1A is a plan view and FIG. 1B is a cross-sectional view showing a semiconductor device according to an embodiment of the present invention.

FIG. 2A is a plan view and FIG. 2B is a cross-sectional view showing a semiconductor device according to the embodiment of the present invention.

FIG. 3 is a plan view showing a semiconductor device according to the embodiment of the present invention.

FIGS. 4A and 4B are cross-sectional views showing the semiconductor device according to the embodiment of the present invention.

FIG. 5 is a plan view showing a semiconductor device according to the embodiment of the present invention.

FIG. 6 is a plan view showing a semiconductor device according to the embodiment of the present invention.

FIG. 7 is a plan view showing a semiconductor device according to the embodiment of the present invention.

FIG. 8 is a plan view showing a semiconductor device according to the embodiment of the present invention.

FIG. 9 is a cross-sectional view showing a method for manufacturing a semiconductor device according to an embodiment of the present invention.

FIG. 10 is a cross-sectional view showing the method for manufacturing a semiconductor device according to the embodiment of the present invention.

FIG. 11 is a cross-sectional view showing the method for manufacturing a semiconductor device according to the embodiment of the present invention.

FIGS. 12A and 12B are cross-sectional views showing the method for manufacturing a semiconductor device according to the embodiment of the present invention.

FIG. 13 is a cross-sectional view showing the method for manufacturing a semiconductor device according to the embodiment of the present invention.

FIGS. 14A and 14B are cross-sectional views showing the method for manufacturing a semiconductor device according to the embodiment of the present invention.

### DESCRIPTION OF THE EMBODIMENTS

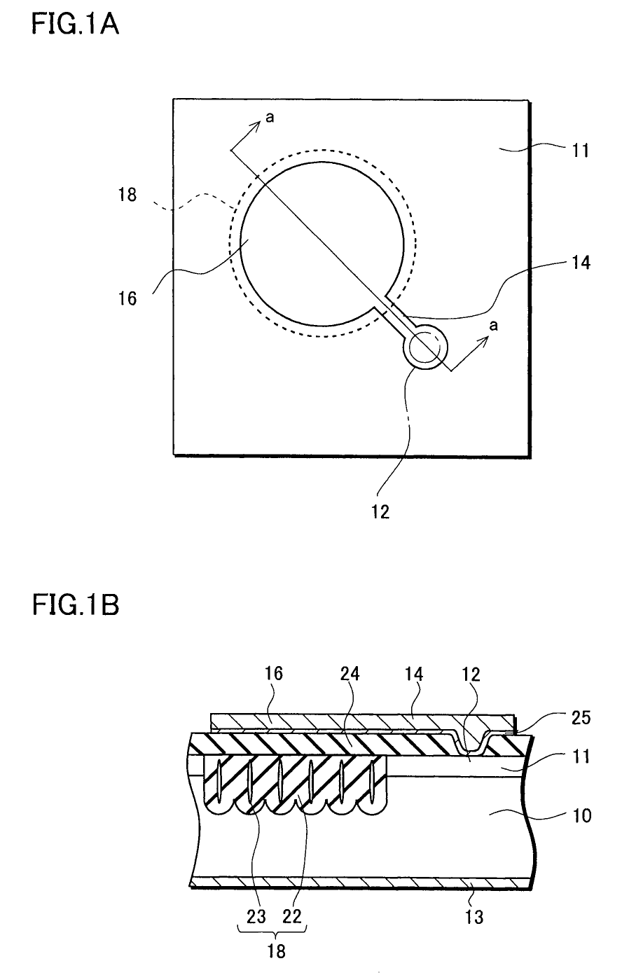

With reference to FIGS. 1 to 14, an embodiment of the present invention will be described in detail below. Moreover, here, description will be given of the case, as an example, where a thick insulating region is formed below an electrode pad in a semiconductor device for high-frequency use.

A semiconductor device of this embodiment includes a semiconductor layer 11, an element region 12 and an insulating region 18. In the element region 12, for example, a Schottky barrier diode, a bipolar transistor and the like are provided.

FIG. 1A is a plan view showing the semiconductor device according to the embodiment of the present invention by taking the Schottky barrier diode as an example. FIG. 1B is a cross-sectional view along the line a-a in FIG. 1A.

With reference to FIGS. 1A and 1B, the semiconductor layer 11 is provided on a high-concentration silicon semiconductor substrate 10, for example, by epitaxial growth or the like. The element region 12 is provided in a surface of the semiconductor layer 11. The element region 12 is formed by allowing a metal layer 25 such as titanium (Ti), for example, to form a Schottky junction with the surface of the semiconductor layer 11 to be a cathode.

Moreover, a wiring electrode (an anode electrode) 14 connected to the element region 12 is provided above the surface of the semiconductor layer 11, and an electrode (a cathode electrode) 13 is provided on a back surface. Furthermore, on the semiconductor layer 11 outside the element region 12, an electrode pad 16 is provided, which is connected to the wiring electrode 14.

In the semiconductor layer 11 below the electrode pad 16, the thick insulating region 18 is disposed. The insulating region 18 is provided in an area approximately overlapping with the electrode pad 16 as indicated by a dashed line in FIG. 1A. A stray capacitance below the electrode pad 16 can be significantly reduced by the insulating region 18. Thus, the insulating region 18 is provided in a pattern larger than that of the electrode pad 16 so that an edge portion of the electrode pad 16 is entirely disposed on the insulating region 18.

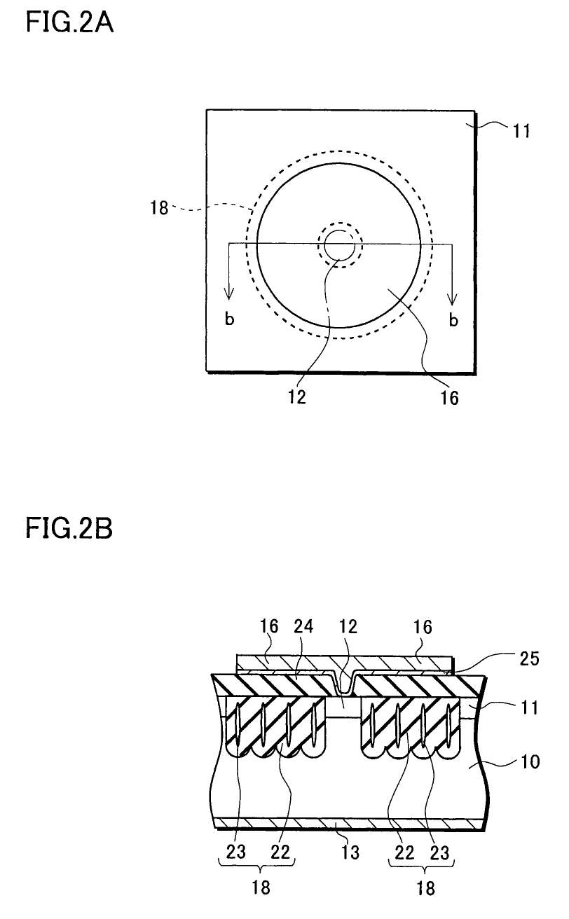

FIG. 2A is a plan view showing another diode and FIG. 2B is a cross-sectional view along the line b-b in FIG. 2A.

In this case, an element region 12 is provided near a center of an electrode pad 16. In a semiconductor layer 11 around the element region 12, a thick insulating region 18 is disposed. The insulating region 18 is provided so as to approximately overlap with the electrode pad 16 except for a portion in which the element region 12 is provided.

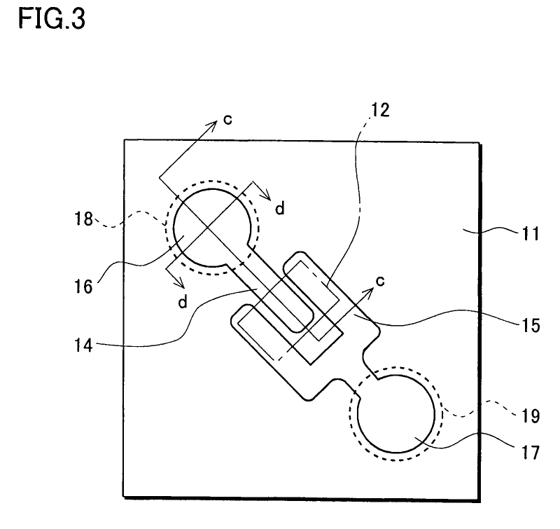

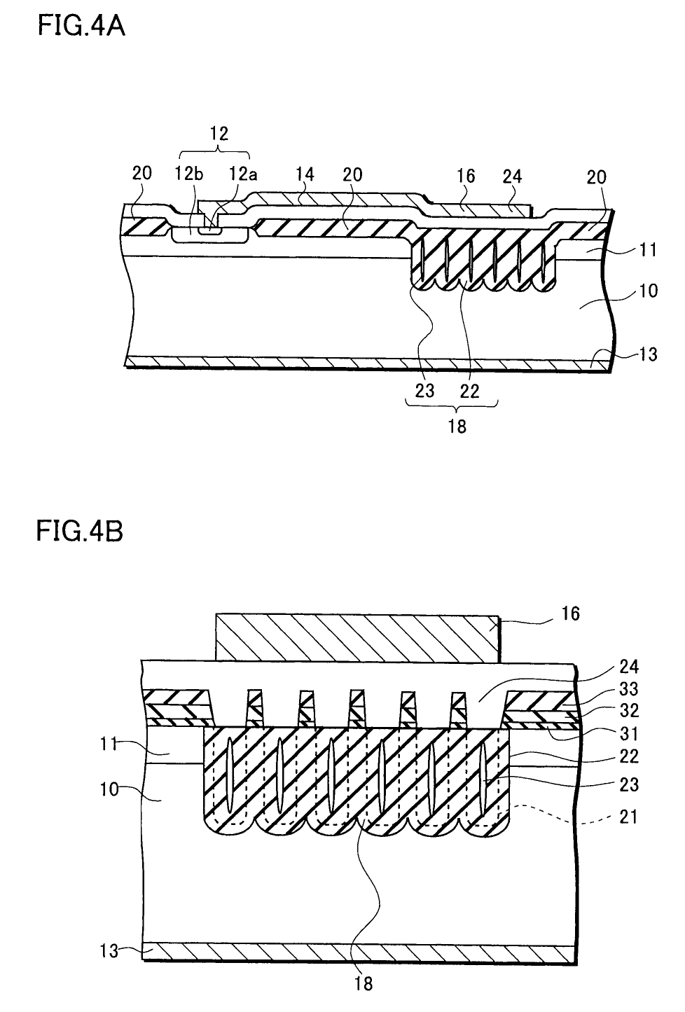

FIG. 3 is a plan view showing the case of a bipolar transistor and FIGS. 4A and 4B are cross-sectional views along the lines c-c and d-d in FIG. 3. An element region 12 in the case of the bipolar transistor has an emitter region 12a and a base region 12b, which are patterned into a stripe pattern preferable for high-frequency use, while using a semiconductor layer 11 as a collector region.

Moreover, on a surface of the semiconductor layer 11, wiring electrodes 14 and 15 are provided, which are connected to the element region 12, respectively. The wiring electrodes 14 and 15 are an emitter electrode and a base electrode, respectively.

Furthermore, on the semiconductor layer 11 outside the element region 12, electrode pads 16 and 17 are provided, which are connected to the wiring electrodes 14 and 15, respectively.

In the semiconductor layer 11 below the electrode pads 16 and 17, thick insulating regions 18 and 19 are disposed. The insulating regions 18 and 19 are provided in areas approximately overlapping with the electrode pads 16 and 17 as indicated by broken lines in FIG. 3.

With reference to FIGS. 4A and 4B, the insulating region 18 will be described. Since the insulating regions 18 and 19 have the same configuration, the following description will be given of the insulating region 18 as an example. Note that the insulating regions 18 shown in FIGS. 1 and 2 also have the same configuration.

The insulating region 18 has an insulating film 22 and void parts 23. Although a manufacturing method will be described later, the insulating film 22 is a thermal oxide film formed by providing trenches 21 in the semiconductor layer 11 and oxidizing insides thereof. A plurality of the trenches are provided so as to be spaced apart from each other by a predetermined distance below the electrode pad 16. The thermal oxide film 22 does not completely fill up the insides of the trenches 21, and the void parts 23 are formed in approximately center portions of the trenches 21, respectively. Meanwhile, the semiconductor layer 11 between the adjacent trenches 21 is thermally oxidized from both sides, and the plurality of trenches 21 are integrated by the thermal oxide film 22. Specifically, the thermal oxide film 22 and the plurality of void parts 23 spaced apart from each other constitute the insulating region 18.

On the insulating region 18, a cover film 24 is provided. The cover film 24 is another insulating film formed by use of a deposition method such as CVD, and is an oxide film, for example.

Alternatively, the cover film 24 is, for example, a metal film such as aluminum (Al) formed by use of a physical deposition method such as vapor deposition and sputtering.

By providing the cover film 24 formed by use of the deposition method on the insulating region 18 as described above, upper portions (near the surface of the semiconductor layer 11) of the void parts 23 are continuously covered with the cover film 24. The film formed by use of the deposition method generally has poor step coverage regardless of the insulating film and the metal film. In this embodiment, the cover film 24 is formed to cover the insulating 18 with poor step coverage. Thus, the void parts 23 that have been formed in the insulating film 18 remain being empty space.

The insulating region 18 can be controlled by a depth of each of the trenches 21. Specifically, even if the trench 21 is formed to have a depth of, for example, 7 μm to 8 μm, the inside thereof can be thermally oxidized.

As to oxidation conditions in this event, oxidation time for a normal LOCOS method may be adopted. Moreover, occurrence of crystal defects caused by a long period of high-temperature oxidation can be suppressed to the same level as that in a normal LOCOS oxidation method.

Therefore, the thick insulating region 18 can be formed without causing the crystal defects or thermal strain in the semiconductor layer 11. For example, in the surface of the semiconductor layer 11 below the wiring electrode 14, a field oxide film 20 (thickness: about 12,000 Å) is provided, which is formed by use of the LOCOS method. However, the insulating region 18 in this embodiment can be formed to have a thickness six to seven times larger than that of the field oxide film. Thus, particularly, a stray capacitance (a capacitance between the electrode pad 16 and an unillustrated back surface electrode (for example, a collector electrode)) below the electrode pad 16 can be significantly reduced.

Furthermore, in this embodiment, the void parts 23 are provided in the insulating region 18. A width of each of the void parts 23 is (although varying depending on a thermal oxidation state), for example, about 0.1 μm to 0.5 μm (here, 0.2 μm). Moreover, a relative permittivity of the void parts 23 is about “1”. Thus, it is possible to further contribute to reduction in the stray capacitance below the electrode pad 16.

Note that, when an insulating film is adopted as the cover film 24, the electrode pad 16 is formed by further providing a metal layer such as aluminum on the cover film 24. Meanwhile, when a metal layer such as aluminum is adopted as the cover film 24, the electrode pad can be formed by use of the cover film 24.

FIGS. 5 to 8 are plan views showing patterns of the trenches 21 in the surface of the semiconductor layer 11 below the electrode pad 16. The trenches 21 are formed by etching the semiconductor layer 11 indicated by hatching.

In this embodiment, the thermal oxide film 22 is formed on the insides of the trenches 21 and in the semiconductor layer 11 on the outsides of the trenches 21 by thermal oxidation of the trenches 21. In this event, the thermal oxide film 22 grown on the insides of the trenches 21 does not fill up the trenches 21. Moreover, a distance between the adjacent trenches 21 and an opening width thereof are selected so that the semiconductor layer 11 between the adjacent trenches 21 is completely insulated by the thermal oxide film 22 grown outward in the semiconductor layer 11. Specifically, an opening width w1 of each of the trenches 21 is set larger than a distance w2 between the adjacent trenches 21, and the void parts 23 (see FIGS. 4A and 4B) are formed.

Technically, a ratio between a proportion of the oxide film grown toward the inside of the silicon substrate and a proportion of the oxide film grown toward the outside of the silicon substrate is 0.9/1.1. Thus, in the case where a ratio between the width w1 of the trench 21 and the distance (a width of the semiconductor layer 11) w2 between the trenches 21 is set to w2/w1=0.9 μm/1.1 μm, when the trenches 21 are filled up with the grown thermal oxide film 22, the portions of the thermal oxide film grown toward the inside of the semiconductor layer 11 also come into contact with each other. Therefore, in this embodiment, by setting w2/w1<0.9 μm/1.1 μm, the semiconductor layer 11 between the adjacent trenches 21 can be completely thermally oxidized from both sides while forming the void parts 23 in the trenches 21.

As an example, the opening width w1 of the trench 21 is 1.5 μm and the distance w2 between the trenches 21 is 0.8 μm.

FIG. 5 shows a ring-shaped pattern of the trenches 21. In the semiconductor layer 11 below the electrode pads 16 and 17, such ring-shaped trenches 21 are formed, each of which has the opening width w1. The adjacent (inner and outer) trenches 21 are separated from each other by the distance w2.

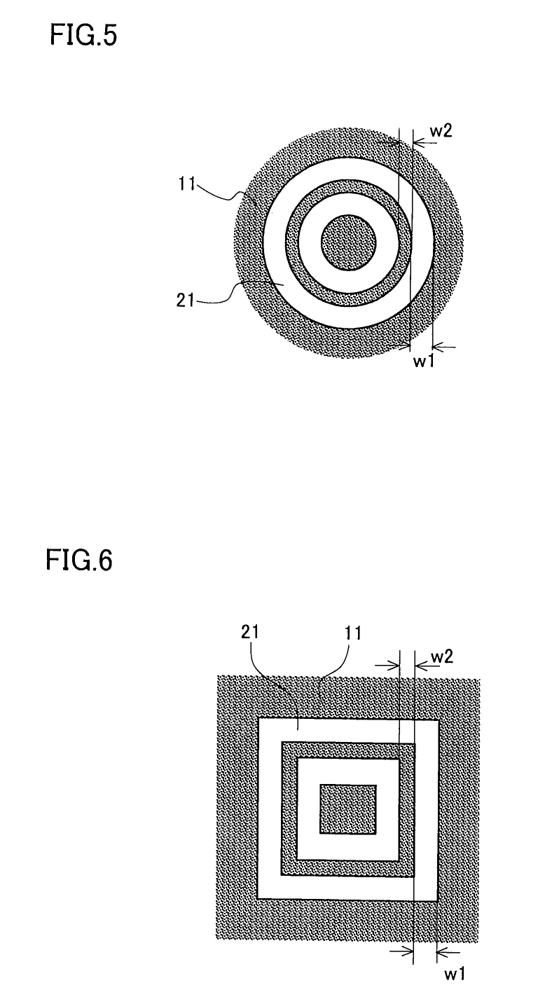

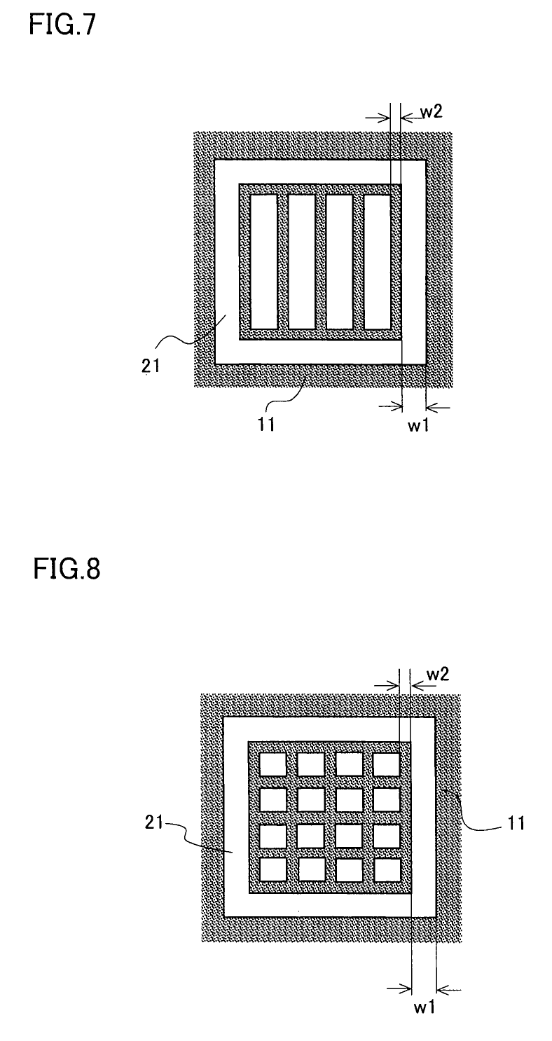

FIG. 6 shows the case where the trenches 21 are formed in a square belt-like pattern. FIG. 7 shows the case where the trenches 21 are formed in a stripe pattern. FIG. 8 shows the case where the trenches 21 are arranged so as to leave the semiconductor layer 11 in a lattice pattern. Note that each of the above patterns is an example and, as long as the opening width w1 of the trench 21 and the distance w2 between the trenches 21 are set in the above ratio, various modified examples are possible without being limited to the patterns shown in FIGS. 5 to 8.

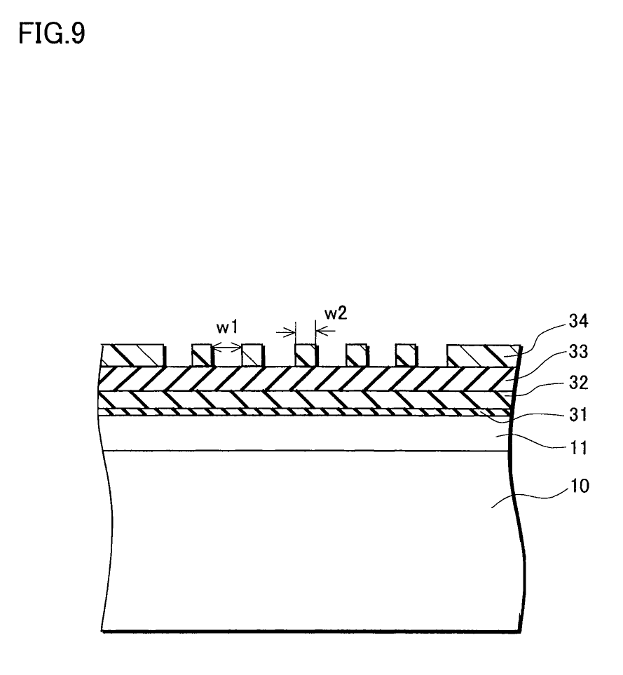

Next, with reference to FIGS. 9 to 14, description will be given of a method for manufacturing a semiconductor device according to the present invention.

The method for manufacturing a semiconductor device according to the present invention is a method for manufacturing a semiconductor device in which an element region and an insulating region are formed in a semiconductor layer. The method includes the steps of: forming trenches in the semiconductor layer outside a formation region of the element region; forming an insulating film in the trenches so as not to completely fill up the trenches; forming a cover film over the trenches and forming the insulating region having void parts therein; and forming the element region in the semiconductor layer.

Note that FIGS. 9 to 14 mainly show the section of the insulating region 18 (the same for the insulating region 19).

First step (FIGS. 9 to 11): forming trenches in a semiconductor layer outside a formation region of an element region.

A high-concentration silicon semiconductor substrate 10 having a semiconductor layer 11 formed thereon by epitaxial growth or the like, for example, is prepared. Thereafter, trenches are formed in the semiconductor layer 11 in a formation region of an electrode pad outside the formation region of the element region.

First, as shown in FIG. 9, a thin oxide film (thermal oxide film) 31 is formed on the semiconductor layer 11, and a nitride film 32 is deposited thereon by vapor growth. The oxide film 31 has a thickness of, for example, about 500 Å, and the nitride film 32 has a thickness of, for example, about 1000 Å. Thereafter, an oxide film 33 is deposited thereon by vapor growth. The oxide film 33 has a thickness of, for example, about 2000 to 3000 Å. These films serve as a mask for forming trenches. Note that, although not shown in the drawings, in the cases of the Schottky barrier diodes shown in FIGS. 1 and 2, an oxide film (about 6000 Å), a TEOS (TetraEthyl OrthoSilicate) film (about 3000 Å), a nitride film (about 1000 Å), a TEOS film (about 6000 Å) and the like, for example, are deposited in this order from a surface of the semiconductor layer 11 for further reducing a capacitance.

Next, resist patterning is performed. First, a photoresist is applied onto the entire surface. Thereafter, the photoresist is exposed and developed according to a mask having a pattern as shown in FIGS. 5 to 8 described above. Thus, a resist pattern 34 is formed. A width w1 of an opening of the resist pattern 34 is a width of an opening of the trench, and a width w2 of the resist pattern 34 is a distance between the trenches. Specifically, the width w2 of the resist pattern 34 is set smaller than the width w1 of the opening. For example, the width w1 of the opening is 1.5 μm and the width w2 of the resist pattern is 0.8 μm.

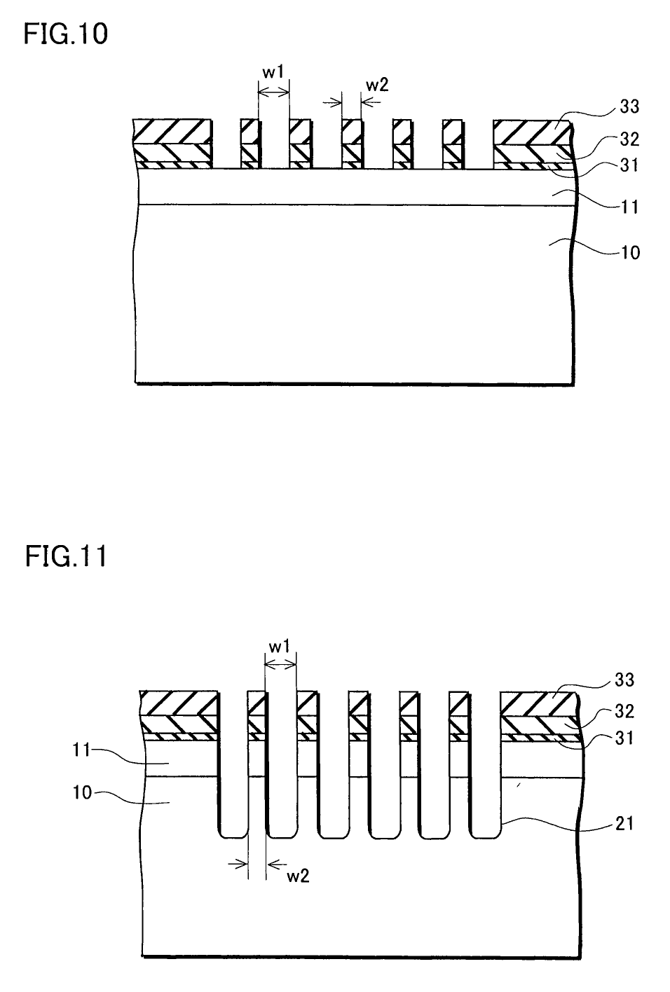

Subsequently, as shown in FIG. 10, by using the resist pattern 34 as a mask, the oxide film 33, the silicon nitride film 32 and the oxide film 31 are dry-etched to remove the photoresist film 34.

Furthermore, as shown in FIG. 11, by using the oxide film 33, the silicon nitride film 32 and the oxide film 31 as a mask, the semiconductor layer 11 is anisotropically etched to form trenches 21, each having a depth of, for example, about 7 μm to 8 μm. A width w1 of an opening of the trench 21 is about 1.5 μm and a distance w2 between the adjacent trenches 21 is about 0.8 μm.

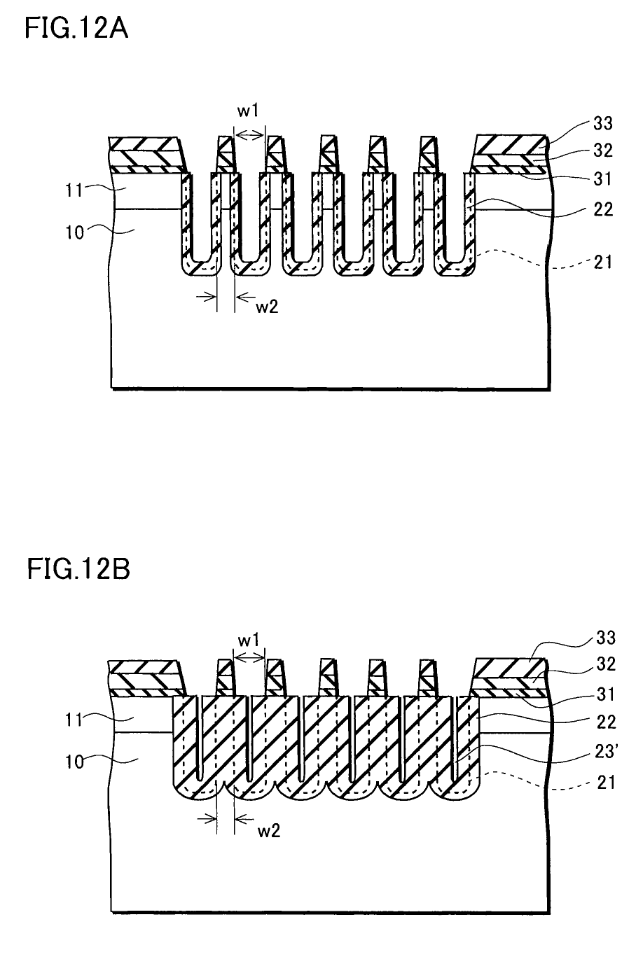

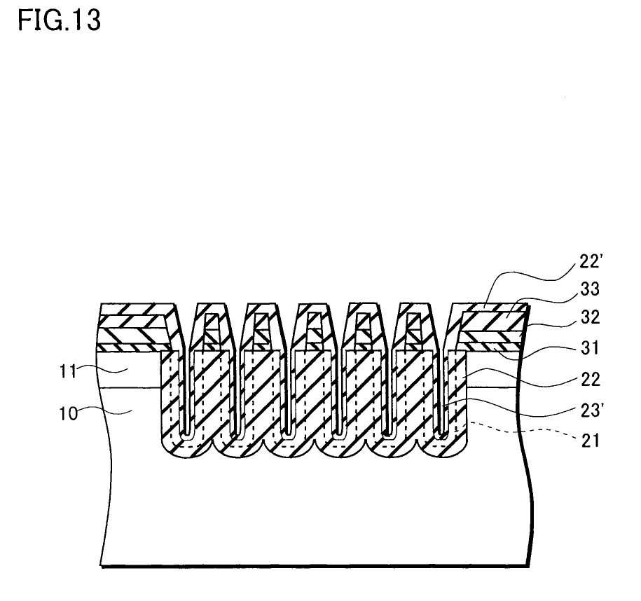

Second step (FIGS. 12 and 13): forming an insulating film in the trenches so as not to completely fill up the trenches.

Thereafter, thermal oxidation is performed in a state of leaving the oxide film 33 as shown in FIGS. 12A and 12B to form an insulating film in the trenches 21 so as not to completely fill up the trenches 21.

Specifically, thermal oxidation is performed in a steam atmosphere of 1100° C. for 170 minutes, for example, to form thermal oxide films 22. The oxidation is extended toward inside of the semiconductor layer 11 and is also grown in the trenches 21 on the outside of the semiconductor layer 11. Accordingly, as shown in FIG. 12A, the width of each of the trenches 21 is gradually narrowed. Thereafter, as the oxidation further progresses, void parts 23′ are formed in a state where the trenches 21 are not completely filled up, in other words, in a state of having openings in upper sides thereof as shown in FIG. 12B. Accordingly, the semiconductor layer 11 between the adjacent trenches 21 is completely insulated by the thermal oxide films 22, and the thermal oxide films 22 are integrated.

Note that, when a width of each of the void parts 23′ is too large after the thermal oxidation in this step, an insulating film 22′ may be additionally formed. The void parts 23′ having the openings in the upper sides are covered with a cover film in a subsequent step. However, if the width of the void part 23′ is too large after the thermal oxidation in this step, there is a risk that the inside thereof is filled up with the cover film. Thus, the void parts 23′ can be reduced to a desired width by deposition of a TEOS film 22′ or the like as shown in FIG. 13.

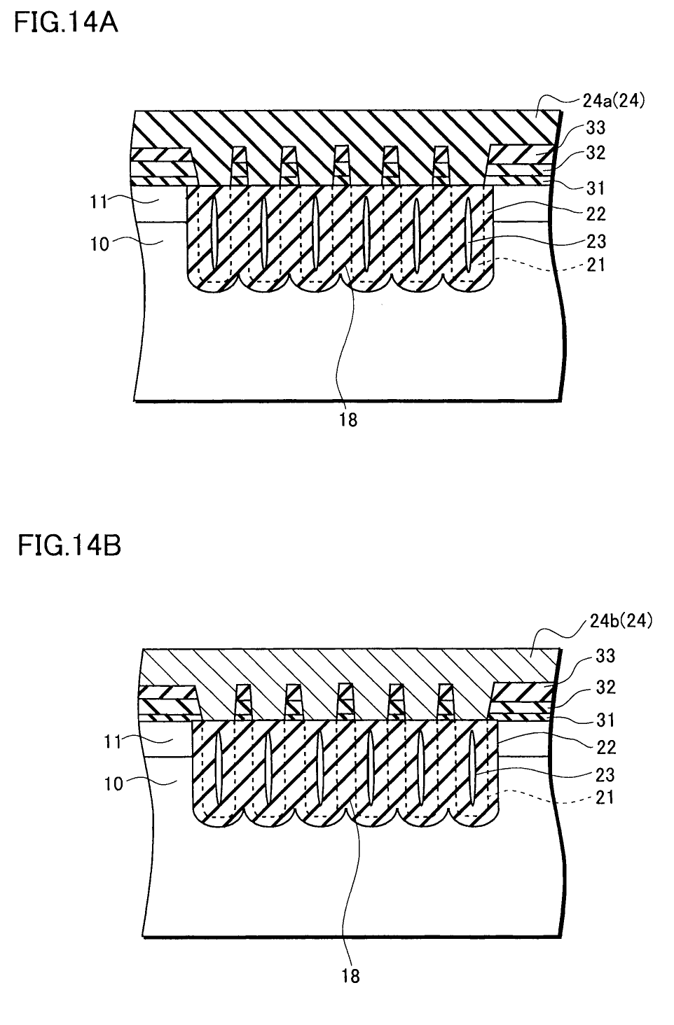

Third step (FIG. 14): forming a cover film over the trenches and forming an insulating region having void parts therein.

A cover film 24 such as an insulating film and a metal film is formed over the trenches 21 by use of a deposition method. Specifically, an oxide film 24a is deposited by low-temperature CVD (Chemical Vapor Deposition) or by CVD using decomposition of TEOS. The cover film 24a has a thickness of, for example, about 8000 Å (FIG. 14A). As the cover film, a PSG (Phospho Silicate Glass) film may be used. The PSG film is hardly deposited in a narrow portion compared with the TEOS film, and thus can cover the trenches without filling up the void parts 23.

Alternatively, a metal film 24b such as aluminum is formed, for example, by use of a physical deposition method. The physical deposition method is vapor deposition or sputtering. Although described later, the metal film 24b may be used to form an electrode pad 16. In this case, the metal film 24b has a thickness of about 1 μm when gold (Au) is adopted, for example, in the case of a bipolar transistor or has a thickness of about 2.5 μm when aluminum (Al) is adopted, for example, in the case of a Schottky barrier diode (FIG. 14B).

Accordingly, upper sides (near the surface of the semiconductor layer 11) of the trenches 21 are continuously covered with the cover film 24. Thus, an insulating region 18 having a plurality of void parts 23 disposed therein is formed.

The film formed by use of the deposition method generally has poor step coverage. In this embodiment, the cover film 24 is formed to cover the insulating 18 with poor step coverage. Thus, the void parts 23 that have been formed in the insulating film 18 remain being empty space.

Each of the void parts 23 has a width of, for example, about 0.1 μm to 0.5 μm (here, 0.2 μm).

The depth of the trench 21 is, for example, 7 μm to 8 μm, which is much larger than a thickness limit (for example, 12,000 Å) of an oxide film formed by use of a LOCOS method. Thus, it is possible to significantly contribute to reduction in a capacitance below the electrode pad 16.

In addition, since a relative permittivity of the void parts 23 is about “1”, the capacitance below the electrode pad 16 can be further reduced.

Fourth step (FIGS. 1 to 4A): forming the element region in the semiconductor layer.

In manufacturing of a semiconductor device for high-frequency use, the thermal oxide film 22 in the insulating region 18 having a thickness of about 8 μm is formed in an arrangement portion of the electrode pad as described above. Moreover, by use of a normal LOCOS method, a field oxide film is formed on the surface of the semiconductor layer 11 to be a formation region of a wiring electrode, for example. Subsequently, after the cover film 24 is formed, diffusion regions such as an emitter region 12a and a base region 12b are formed, for example, to form an element region 12.

Next, for example, a wiring electrode material such as aluminum is deposited by sputtering or the like to form electrode pads 16 and 17 on the insulating regions 18 and 19 by resist patterning. Specifically, the electrode pads 16 and 17 approximately overlap with the insulating regions 18 and 19 and are connected to the element region 12. Moreover, at the same time, wiring electrodes 14 and 15 are also formed (by use of the same metal layers as those of the electrode pads 16 and 17).

Particularly, in the Schottky barrier diode, when the insulating region 18 is provided to reduce the capacitance below the electrode pad 16, the electrode pad 16 may be formed by use of the metal film 24b.

Moreover, in the case of the Schottky barrier diode as shown in FIGS. 1 and 2, the element region 12 is formed by depositing a metal layer 25 such as titanium (Ti) and tungsten (W) on the surface of the semiconductor layer 11 and forming a Schottky junction therebetween in the fourth step (element region formation step). Thereafter, the wiring metal layer 14 and the electrode pad 16 such as aluminum (Al) are formed.

The Schottky metal layer 25 may be provided only in the element region 12 and may be formed to have the same pattern as that of the wiring electrode layer 14. However, in the latter case, when the metal film 24b is adopted as the cover film 24 as described above, the Schottky metal layer 25 (thickness: for example, 2000 Å) is disposed below the cover layer 24b in FIG. 14B. Meanwhile, when the Schottky metal layer 25 is titanium (Ti), the Schottky metal layer 25 is likely to enter into the void parts 23 and may fill up the void parts 23. Specifically, in the case where the Schottky metal layer 25 is provided in the same pattern as that of the wiring electrode layer 14, the Schottky metal layer 25 and the electrode pad 16 may be formed after the cover film 24a made of an insulating film is formed as shown in FIG. 14A.

In this embodiment, the description was given by taking, as an example, the case where the insulating region 18 is provided below the electrode pad 16 for reducing the capacitance. However, without being limited thereto, the insulating region 18 of this embodiment may be formed instead of LOCOS oxide films for element isolation (for example, the field oxide films 20 at both ends in FIG. 4A). Moreover, the insulating region 18 of this embodiment may be used to form the LOCOS oxide film below the wiring electrode 14.

According to this embodiment, the insulating region having the void parts therein is provided by oxidizing the insides of the trenches provided in the silicon semiconductor layer so as not to completely fill up the trenches. Specifically, a required thickness of the insulating region can be achieved by controlling the depth of the trenches.

As to oxidation conditions in this event, oxidation time for a normal LOCOS method may be adopted. Moreover, occurrence of crystal defects caused by a long period of high-temperature oxidation can be suppressed to the same level as that in a normal LOCOS oxidation method.

For example, by forming the trenches to have a larger depth (for example, 12,000 Å or more), the insulating region having a thickness larger (for example, six to seven times larger) than that of an oxide film formed by oxidation using the normal LOCOS method can be formed. Furthermore, the capacitance of the insulating region can be reduced by the void parts formed inside the trenches.

Particularly, by providing, below the electrode pad, the insulating region as thick as, for example, about 7 to 8 μm, a stray capacitance in the electrode wiring portion can be significantly reduced. Thus, high-frequency characteristics of a high-frequency semiconductor device can be significantly improved. Therefore, the high-frequency characteristics such as power gain characteristics can be improved. Moreover, since the insulating region having a sufficient thickness can be obtained, a single-layer structure is enough for electrode wiring. Thus, manufacturing steps can be simplified.

What is claimed is:

1. A semiconductor device comprising:
a semiconductor layer comprising an element region and an insulating region; and
a semiconductor element formed in the element region,
wherein the insulating region comprises an insulating film formed in the semiconductor layer to define a void.

2. The semiconductor device of claim 1, further comprising a cover film disposed on the void.

3. The semiconductor device of claim 1, further comprising an electrode pad connected to the semiconductor element and disposed on the insulating region.

4. The semiconductor device of claim 1, further comprising an additional void defined by the insulating film.

5. The semiconductor device of claim 2, wherein the cover film comprises another insulating film or a metal film.

6. A method of manufacturing a semiconductor device, comprising:
providing a semiconductor layer;
forming a trench in the semiconductor layer;
forming an insulating film in the trench so as not to fill the trench completely so that a void is formed in the trench;
forming a cover film on the trench; and
forming an semiconductor element in the semiconductor layer outside the trench.

7. The method of claim 6, wherein the insulating film is formed by thermally oxidizing the semiconductor layer.

8. The method of claim 6, further comprising forming an electrode pad on the insulating film so as to be connected to the semiconductor element.

9. The method of claim 6, wherein the cover film comprises another insulating film formed by a deposition method.

10. The method of claim 6, wherein the cover film comprises a metal film formed by a physical deposition method.

11. A method of manufacturing a semiconductor device, comprising:
providing a semiconductor layer;
forming a plurality of trenches in the semiconductor layer;
thermally oxidizing inside walls of the trenches so as to grow an insulating film so that voids are formed in the trenches;
forming a cover film on the trenches; and
forming an semiconductor element in the semiconductor layer outside the trenches,
wherein the oxidation of the inside walls of the trenches is performed so that portions of the semiconductor layer between the trenches are completely oxidized.

12. The method of claim 11, further comprising forming an electrode pad on the trenches so as to be connected to the semiconductor element.

13. The method of claim 11, wherein the cover film comprises another insulating film formed by a deposition method.

14. The method of claim 11, wherein the cover film comprises a metal film formed by a physical deposition method.

15. The method of claim 11, wherein the trenches are formed so that a distance between neighboring edges of a pair of neighboring trenches is shorter than a width of the trenches at an opening thereof.

16. A semiconductor device comprising:
a semiconductor substrate;
a semiconductor element formed on the substrate;
an electrode pad formed on the substrate and connected to the semiconductor element; and
an insulating region formed in the substrate under the electrode pad and comprising an insulating portion and an void portion defined by the insulating portion.
